(19) United States
(12) Patent Application Publication
(10) Pub. No.: US 2015/0351236 A1
(43) Pub. Date: Dec. 3, 2015

(54) METHOD FOR MANUFACTURING METAL FOIL-CLAD LAMINATE

(71) Applicants: MITSUBISHI GAS CHEMICAL COMPANY, INC., Tokyo (JP); MGC ELECTROTECHNO CO., LTD., Fukushima (JP)

(72) Inventors: Yoshihiro KATO, Tokyo (JP); Takeshi NOBUKUNI, Fukushima (JP); Hiroyuki MATSUMOTO, Fukushima (JP); Mitsunori KUBOKI, Fukushima (JP)

(73) Assignees: MITSUBISHI GAS CHEMICAL COMPANY, INC., Tokyo (JP); MGC ELECTROTECHNO CO., LTD, Fukushima (JP)

(21) Appl. No.: 14/649,021

(22) PCT Filed: Dec. 6, 2013
(86) PCT No.: PCT/JP2013/082842

§ 371 Date: Jun. 2, 2015

(30) Foreign Application Priority Data
Dec. 6, 2012 (JP) 2012-267446
Dec. 28, 2012 (JP) 2012-287278

(51) Int. Cl. H05K 1/03; H05K 1/02; B32B 37/06; H05K 3/00; B32B 37/18; B32B 37/10

(52) U.S. Cl. CPC H05K 1/0373; B32B 37/18; B32B 37/1018; B32B 37/10; B32B 37/06; H05K 3/00; H05K 1/0271; B32B 2307/202; B32B 2457/08

(57) ABSTRACT

A method for manufacturing a metal foil-clad laminate in which the occurrence of voids and unevenness is suppressed compared with conventional ones even when a prepreg obtained from a curable resin composition containing a relatively large amount of an inorganic filler is used. A laminate and a metal foil-clad laminate has excellent moldability, a low thermal expansion coefficient, and high glass transition temperature and is excellent in the peel strength of the metal foil. A method comprises disposing one or more prepregs between metal foils so that the one or more prepregs are in contact with metal surfaces, and heating and pressurizing the one or more prepregs and the metal foils in a vacuum atmosphere to laminate the prepregs and the metal foils to obtain a metal foil-clad laminate; and further subjecting the metal foil-clad laminate to heating and pressurization treatment in a vacuum atmosphere.

### TECHNICAL FIELD

The present invention relates to a method for manufacturing a metal foil-clad laminate using a prepreg fabricated using a resin composition, and the like.

### BACKGROUND ART

In recent years, higher integration, higher functionality, and higher density mounting of semiconductors widely used in electronic equipment, communication instruments, personal computers, and the like have accelerated increasingly, and the demand for the properties and high reliability of metal foil-clad laminates for semiconductor plastic packages has increased more than ever before.

As the properties required of metal foil-clad laminates for semiconductor plastic packages, the reduction of the thermal expansion coefficient and high thermal conductivity are required. Examples of methods for achieving these properties generally include incorporating a resin composition, a raw material, with a large amount of an inorganic filler.

### LIST OF PRIOR ART DOCUMENTS

### Patent Document

### Patent Document 1: Japanese Patent Laid-Open No. 2008-075012

### Patent Document 2: Japanese Patent Laid-Open No. 2012-119461

### SUMMARY OF INVENTION

### Problems to be Solved by Invention

As methods for manufacturing a metal foil-clad laminate for a semiconductor plastic package, a manufacturing method is generally known which comprises the steps of stacking one or several prepregs, disposing a metal foil such as copper or aluminum on one surface or both surfaces of the stack, if necessary, and subjecting such a configuration to lamination molding using a multistage vacuum press or an autoclave (Patent Document 1). However, when the resin composition is incorporated with a large amount of an inorganic filler in order to reduce the thermal expansion coefficient of the laminate, a disadvantage of this manufacturing method is that voids, and streaky unevenness at the laminate ends occur.

As another manufacturing method, there is also proposed a method comprising the steps of first disposing a prepreg between metal foils or the like so that the prepreg is in contact with the metal surfaces, vacuum-laminating them while heating and pressurizing them, and then curing the thermosetting resin in the prepreg in a dryer to manufacture a metal foil-clad laminate (Patent Document 2). However, also, a disadvantage of this manufacturing method is that during heating in the dryer, air remaining in the prepreg thermally expands to swell the metal foils, resulting in voids.

The present invention has been made in view of the above problems. Specifically, it is an object of the present invention to provide a method for manufacturing a metal foil-clad laminate in which the occurrence of voids and unevenness is suppressed compared with conventional ones even when a prepreg obtained from a curable resin composition containing a relatively large amount of an inorganic filler is used. In addition, it is another object of the present invention to provide a metal foil-clad laminate excellent in various properties required of a printed wiring board material, particularly heat resistance and a thermal expansion coefficient, and the like.

### Means for Solving Problems

The present inventors have diligently advanced study and, as a result, found that the above problems can be solved by combining two lamination methods, a vacuum heating and pressurization adhesion step and a vacuum heating and pressurization lamination molding step, arriving at the present invention.

Specifically, the present invention provides the following <1> to <8>.

<1>

A method for manufacturing a metal foil-clad laminate, comprising:

(A) an adhesion step of disposing one or more prepregs between metal foils so that the one or more prepregs are in contact with metal surfaces, and heating and pressurizing the one or more prepregs and the metal foils in a vacuum atmosphere to laminate the one or more prepregs and the metal foils to obtain a metal foil-clad laminate; and

(B) a lamination molding step of further subjecting the metal foil-clad laminate to heating and pressurization treatment in a vacuum atmosphere.

<2>

The method for manufacturing the metal foil-clad laminate according to <1>, wherein in the adhesion step (A), the heating and pressurization treatment is carried out under conditions of a degree of vacuum of 0.001 to 1 kPa, a heating temperature of 50 to 180° C., and a pressurization pressure of 1 to 30 kgf/cm².

<3>

The method for manufacturing the metal foil-clad laminate according to <1> or <2>, wherein in the lamination molding step (B), the heating and pressurization treatment is carried out under conditions of a degree of vacuum of 0.01 to 6 kPa, a heating temperature of 100 to 400° C., and a pressurization pressure of 1 to 40 kgf/cm².

<4>

The method for manufacturing the metal foil-clad laminate according to any one of <1> to <3>, wherein in the adhesion step (A), an adhered body having a peel strength of the metal foil of 0.01 to 0.1 kN/m is obtained.

<5>

The method for manufacturing the metal foil-clad laminate according to any one of <1> to <4>, wherein in the lamination molding step (B), the heating and pressurization treatment is performed using any of a multistage press, a multistage vacuum press, or a continuous molding machine.

<6>

The method for manufacturing the metal foil-clad laminate according to any one of <1> to <5>, wherein the prepreg is obtained by impregnating or coating a sheet-like fiber substrate with a curable resin composition comprising a thermosetting resin (a) and an inorganic filler (b).

<7>

The method for manufacturing the metal foil-clad laminate according to <6>, wherein a content of the inorganic filler (b) in the prepreg is 80 to 1100 parts by mass based on 100 parts by mass of the thermosetting resin (a).

<8>

A printed wiring board using for an insulating layer a metal foil-clad laminate obtained by the manufacturing method according to any one of <1> to <7>.

### Advantages of Invention

According to the manufacturing method of the present invention, a metal foil-clad laminate in which the occurrence of voids and unevenness is suppressed can be stably manufactured, and a metal foil-clad laminate excellent in various properties required as a printed wiring board material, particularly heat resistance, a thermal expansion coefficient, and peel strength, can be stably manufactured. Especially, the manufacturing method of the present invention can effectively suppress the occurrence of voids and unevenness also when a prepreg obtained from a curable resin composition containing a relatively large amount of an inorganic filler is used.

### MODE FOR CARRYING OUT INVENTION

Hereinafter, embodiments of the present invention will be described below. The following embodiments are illustrations for describing the present invention, and the present invention is not limited to only the embodiments.

A manufacturing method of the present embodiment comprises (A) the adhesion step of disposing one or more prepregs between metal foils so that the one or more prepregs are in contact with the metal surfaces, and heating and pressurizing the one or more prepregs and the metal foils in a vacuum atmosphere to laminate the one or more prepregs and the metal foils to obtain a metal foil-clad laminate; and (B) the lamination molding step of further subjecting the above metal foil-clad laminate to heating and pressurization treatment in a vacuum atmosphere.

### <Adhesion Step (A)>

First, the adhesion step (A) that is one of the steps constituting the manufacturing method of the present embodiment will be described.

In this adhesion step (A), one or more prepregs are disposed (bonded) between metal foils so that the one or more prepregs are in contact with the metal surfaces, and heated and pressurized to vacuum-laminate the prepreg on the metal foils. More specifically, one or more prepregs are disposed between metal foils so that the one or more prepregs are in contact with the metal surfaces, to provide a laminate, and this laminate is subjected to heating and pressurization treatment in a vacuum atmosphere to obtain a metal foil-clad laminate (adhered body) in which the above metal foils are adhered to the above prepreg. Here, when two or more prepregs are used, the same prepreg may be used, or different prepregs may be used. When different prepregs are used, those different from each other in one or all of the composition of the curable resin composition, the material of the sheet-like fiber substrate, the thickness of the sheet-like fiber substrate, and the like can be used.

In the bonding of the metal foils and the prepreg, various known apparatuses can be used, and, for example, a batch laminator and a roll laminator can be used. In terms of providing smoothness, a batch laminator is preferred.

The heating temperature in the adhesion step (A) is not particularly limited, but in terms of increasing the adhesiveness between the metal foils and the prepreg, the heating temperature in the adhesion step (A) is preferably 50° C. or more, more preferably 60° C. or more, further preferably 70° C. or more, and still further preferably 80° C. or more. In terms of the heat resistance of conveyance PET used in the laminator apparatus, the heating temperature in the adhesion step (A) is preferably 180° C. or less, more preferably 170° C. or less, further preferably 160° C. or less, and still further preferably 150° C. or less.

The time of the adhesion step (A) is not particularly limited, but in terms of sufficiently flowing the resin, the time of the adhesion step (A) is preferably 10 seconds or more, more preferably 15 seconds or more, further preferably 20 seconds or more, and still further preferably 25 seconds or more. In terms of productivity improvement, the time of the adhesion step (A) is preferably 600 seconds or less, more preferably 500 seconds or less, further preferably 400 seconds or less, still further preferably 300 seconds or less, especially preferably 200 seconds or less, and particularly preferably 100 seconds or less.

The degree of vacuum in the adhesion step (A) is not particularly limited, but in terms of preventing the entry of air into the laminate to prevent the occurrence of voids, the degree of vacuum in the adhesion step (A) is preferably 1 kPa or less, more preferably 0.9 kPa or less, further preferably 0.5 kPa or less, still further preferably 0.4 kPa or less, especially preferably 0.3 kPa or less, particularly preferably 0.2 kPa or less, and especially preferably 0.1 kPa or less. The lower limit of the degree of vacuum in the adhesion step (A) is not particularly limited but is preferably 0.001 kPa or more.

The pressure in the adhesion step (A) is not particularly limited, but in terms of flowing the curable resin composition and improving close adhesiveness to the metal foils, the pressure in the adhesion step (A) is preferably 1 kgf/cm² or more, more preferably 3 kgf/cm² or more, and further preferably 5 kgf/cm² or more. In terms of preventing the exudation of the curable resin composition and obtaining film thickness uniformity, the pressure in the adhesion step (A) is preferably 30 kgf/cm² or less, more preferably 25 kgf/cm² or less, further preferably 22 kgf/cm² or less, still further preferably 20 kgf/cm² or less, especially preferably 17 kgf/cm² or less, and particularly preferably 15 kgf/cm² or less.

As the above-described batch laminator or roll laminator, a vacuum laminator can be used. Examples of commercial vacuum laminators include a batch vacuum pressurization laminator MVLP-500/600 manufactured by MEIKI CO., LTD., a batch vacuum pressurization laminator CVP-600 manufactured by Nichigo-Morton Co., Ltd., a vacuum laminator manufactured by KITAGAWA SEIKI CO., LTD, a roll dry coater manufactured by Hitachi Industries Co., Ltd., and a vacuum laminator manufactured by Hitachi AIC Inc.

In the adhered body obtained through the above adhesion step (A), the peel strength of the metal foil from the prepreg is preferably 0.01 to 0.1 kN/m, more preferably 0.02 to 0.1 kN/m. As used herein, the peel strength of the metal foil means a value measured according to Test methods of copper-clad laminates for printed wiring boards, JIS C6481 (see 5.7 Peel Strength), and its measurement conditions are described in Examples described later.

### <Lamination Molding Step (B)>

Next, the lamination molding step (B) that is another step constituting the manufacturing method of the present embodiment will be described.

In this lamination molding step (B), the metal foil-clad laminate (adhered body) obtained in the adhesion step (A) described above is further subjected to heating and pressurization treatment in a vacuum atmosphere to obtain the target metal foil-clad laminate.

The heating temperature in the lamination molding step (B) is not particularly limited, but in terms of still further increasing the adhesiveness between the metal foils and the prepreg and resin curability, the heating temperature in the lamination molding step (B) is preferably 100° C. or more, more preferably 120° C. or more, further preferably 130° C. or more, and still further preferably 150° C. or more. In terms of suppressing the pyrolysis of the epoxy resin and the like, the heating temperature in the lamination molding step (B) is preferably 400° C. or less, more preferably 350° C. or less, further preferably 330° C. or less, and still further preferably 300° C. or less. Here, the heating temperature in the lamination molding step (B) is preferably higher than the heating temperature in the adhesion step (A) described above. By carrying out the lamination molding step (B) at high temperature in this manner, a metal foil-clad laminate better in appearance and various physical properties can be obtained.

The time of the lamination molding step (B) is not particularly limited but is preferably 5 minutes or more, more preferably 10 minutes or more, further preferably 20 minutes or more, and still further preferably 30 minutes or more in terms of still further increasing resin curability. In terms of productivity improvement, the time of the lamination molding step (B) is preferably 300 minutes or less, more preferably 280 minutes or less, further preferably 250 minutes or less, still further preferably 240 minutes or less, especially preferably 230 minutes or less, and particularly preferably 220 minutes or less.

The degree of vacuum in the lamination molding step (B) is not particularly limited but is preferably 0.01 kPa or more, more preferably 0.02 kPa or more, further preferably 0.03 kPa or more, and still further preferably 0.05 kPa or more in terms of decreasing the degree of vacuum immediately after the treatment to improve productivity. In terms of preventing the entry of air into the laminate to prevent the occurrence of voids, the degree of vacuum in the lamination molding step (B) is preferably 6 kPa or less, more preferably 5 kPa or less, further preferably 4 kPa or less, still further preferably 3 kPa or less, especially preferably 2 kPa or less, particularly preferably 1 kPa or less, and especially preferably 0.5 kPa or less.

The pressure in the lamination molding step (B) is not particularly limited but is preferably 1 kgf/cm² or more, more preferably 2 kgf/cm² or more, and further preferably 3 kgf/cm² or more in terms of still further improving the close adhesiveness between the prepreg and the metal foils. In terms of preventing the exudation of the curable resin composition and increasing film thickness uniformity, the pressure in the lamination molding step (B) is preferably 40 kgf/cm² or less, more preferably 35 kgf/cm² or less, further preferably 33 kgf/cm² or less, still further preferably 30 kgf/cm² or less, especially preferably 25 kgf/cm² or less, and particularly preferably 20 kgf/cm² or less.

The lamination molding step (B) can be performed using various known apparatuses, for example, a lamination apparatus for a laminate for a printed wiring board or a multilayer plate usually used. Specific examples thereof include a multistage press, a multistage vacuum press, a continuous molding machine, and an autoclave molding machine.

### <Prepreg>

The prepreg used in the adhesion step (A) described above comprises a curable resin composition and a sheet-like fiber substrate. This prepreg can be obtained by impregnating or coating the sheet-like fiber substrate with the curable resin composition and heating and drying the sheet-like fiber substrate with the curable resin composition as required.

### [Curable Resin Composition]

The curable resin composition of the above prepreg preferably contains a thermosetting resin (a) and an inorganic filler (b).

The thermosetting resin (a) is not particularly limited as long as it is a thermosetting resin generally used for a printed wiring board material. Examples thereof include epoxy resins, cyanate compounds, phenolic resins, maleimide compounds, and BT resins. One of these can be used, or two or more of these can be used in combination.

The epoxy resins are not particularly limited as long as they are compounds having two or more epoxy groups in one molecule and having no halogen atom in the molecular skeleton. Examples thereof include bisphenol A-based epoxy resins, bisphenol F-based epoxy resins, phenol novolac-based epoxy resins, cresol novolac-based epoxy resins, bisphenol A novolac-based epoxy resins, trifunctional phenol-based epoxy resins, tetrafunctional phenol-based epoxy resins, naphthalene-based epoxy resins, biphenyl-based epoxy resins, aralkyl novolac-based epoxy resins, alicyclic epoxy resins, polyol-based epoxy resins, glycidyl amines, glycidyl esters, compounds obtained by epoxidizing the double bond of butadiene or the like, and compounds obtained by the reaction of hydroxyl group-containing silicone resins with epichlorohydrin. One of these can be used alone or two or more of these can be used in combination according to the purpose. Among these, phenol phenyl aralkyl novolac-based epoxy resins, phenol biphenyl aralkyl-based epoxy resins, naphthol aralkyl-based epoxy resins, anthraquinone-based epoxy resins, and polyoxynaphthylene-based epoxy resins are preferred particularly in terms of improving flame retardancy or in terms of reducing thermal expansion.

Examples of the cyanate compounds include, but are not particularly limited to, naphthol aralkyl-based cyanate compounds, novolac-based cyanates, biphenyl aralkyl-based cyanates, bis(3,5-dimethyl 4-cyanatophenyl)methane, bis(4-cyanatophenyl)methane, 1,3-dicyanatobenzene, 1,4-dicyanatobenzene, 1,3,5-tricyanatobenzene, 1,3-dicyanatonaphthalene, 1,4-dicyanatonaphthalene, 1,6-dicyanatonaphthalene, 1,8-dicyanatonaphthalene, 2,6-dicyanatonaphthalene, 2,7-dicyanatonaphthalene, 1,3,6-tricyanatonaphthalene, 4,4′-dicyanatobiphenyl, bis(4-cyanatophenyl)ether, bis(4-cyanatophenyl)thioether, bis(4-cyanatophenyl)sulfone, and 2,2′-bis(4-cyanatophenyl)propane. One of these can be used alone or two or more of these can be used in combination according to the purpose. Among these, naphthol aralkyl-based cyanate compounds, novolac-based cyanates, and biphenyl aralkyl-based cyanates are particularly preferred because they have excellent flame retardancy and high curability, and the thermal expansion coefficients of the cured products are low.

Examples of the phenolic resins include, but are not particularly limited to, cresol novolac-based phenolic resins, phenol novolac resins, alkylphenol novolac resins, bisphenol A-based novolac resins, dicyclopentadiene-based phenolic resins, Xylok-based phenolic resins, terpene-modified phenolic resins, polyvinyl phenols, naphthol aralkyl-based phenolic resins, biphenyl aralkyl-based phenolic resins, naphthalene-based phenolic resins, and aminotriazine novolac-based phenolic resins. One of these can be used alone or two or more of these can be used in combination according to the purpose. Among these, in terms of water absorbency and heat resistance, cresol novolac-based phenolic resins, aminotriazine novolac-based phenolic resins, naphthalene-based phenolic resins, naphthol aralkyl-based phenolic resins, and biphenyl aralkyl-based phenolic resins are preferred, and especially, cresol novolac-based phenol compounds, naphthol aralkyl-based phenolic resins, and biphenyl aralkyl-based phenolic resins are more preferred.

The maleimide compounds are not particularly limited as long as they are, for example, compounds having one or more maleimide groups in one molecule. Specific examples thereof include, but are not particularly limited to, N-phenylmaleimide, N-hydroxyphenylmaleimide, bis(4-maleimidophenyl)methane, 2,2-bis{4-(4-maleimidophenoxy)-phenyl}propane, bis(3,5-dimethyl-4-maleimidophenyl)methane, bis(3-ethyl-5-methyl-4-maleimidophenyl)methane, bis(3,5-diethyl-4-maleimidophenyl)methane, polyphenylmethane maleimide compounds, prepolymers of these maleimide compounds, or prepolymers of maleimide compounds and amine compounds. One of these can be used alone or two or more of these can be used in combination according to the purpose. Among these, bis(4-maleimidophenyl)methane, 2,2-bis{4-(4-maleimidophenoxy)-phenyl}propane, bis(3-ethyl-5-methyl-4-maleimidophenyl)methane, and polyphenylmethane maleimide are preferred.

The BT resins are obtained by heating and mixing a cyanate compound and a maleimide compound without a solvent or a cyanate compound and a maleimide compound dissolved in an organic solvent such as methyl ethyl ketone, N methylpyrrolidone, dimethylformamide, dimethylacetamide, toluene, or xylene, to prepolymerize the cyanate compound and the maleimide compound.

The cyanate compound and the maleimide compound used in the synthesis of the BT resin are not particularly limited, and, for example, the above-described cyanate compounds and maleimide compounds can be used. Among these, naphthol aralkyl-based cyanate compounds, novolac-based cyanate compounds, and biphenyl aralkyl-based cyanates are preferred as the cyanate compound in terms of the flame retardancy, curability, and low thermal expansion coefficient of the obtained printed wiring board. As the maleimide compound, bis(4-maleimidophenyl)methane, 2,2-bis{4-(4-maleimidophenoxy)-phenyl}propane, bis(3-ethyl-5-methyl-4-maleimidophenyl)methane, and polyphenylmethane maleimide are preferred.

In addition, a silicone rubber powder may be added to the thermosetting resin (a) as required. The silicone rubber powder is a fine powder of an addition polymer of vinyl group-containing dimethylpolysiloxane and methylhydrogenpolysiloxane. Blending the silicone rubber powder provides the effect of lower thermal expansion. But, the silicone rubber powder has strong aggregability, and the dispersibility of the silicone rubber powder in the curable resin composition may be poor. Therefore, it is preferred to use a silicone rubber powder whose surface is coated with a silicone resin to improve dispersibility. This silicone resin with which the surface is coated is not particularly limited, but polymethylsilsesquioxane in which siloxane bonds are crosslinked in the form of a three-dimensional network is preferred. The average particle diameter (D50) of the silicone rubber powder is not particularly limited but is preferably 0.5 to 15 μm considering dispersibility.

Here, D50 is a median diameter, and is a particle diameter at which each of the number or mass on the larger side and the number or mass on the smaller side when the measured particle size distribution of a powder is divided into two accounts for 50% of that of the whole powder, and D50 is generally measured by a wet laser diffraction-scattering method.

The amount of the silicone rubber powder blended is not particularly limited. In terms of the moldability of the obtained curable resin composition, the amount of the silicone rubber powder blended is preferably 100 parts by mass or less based on 100 parts by mass of the total of the thermosetting resin (a), and the silicone rubber powder is preferably used particularly in the range of 90 parts by mass or less. The lower limit of the amount of the silicone rubber powder blended is not particularly limited but is preferably 1 part by mass or more, more preferably 3 parts by mass or more, in terms of exhibiting lower thermal expansion.

Further, a curing accelerator can also be used in combination with the thermosetting resin (a) as required. By using the curing accelerator in combination, the curing speed of the obtained curable resin composition can be appropriately adjusted. The curing accelerator used here is not particularly limited as long as it is generally used as a curing accelerator for the thermosetting resin (a). Specific examples thereof include, but are not particularly limited to, organometallic salts of copper, zinc, cobalt, nickel, and the like, imidazoles and derivatives thereof, and tertiary amines. One of these can be used alone or two or more of these can be used in combination according to the purpose.

In addition, a silicone resin powder as a flame-retardant aid can also be used in combination with the thermosetting resin (a) as required. The silicone resin powder used as a flame-retardant aid here is different from the silicone resin used for the surface coating of the silicone rubber powder described above. The amount of the silicone resin powder blended is not particularly limited, but in terms of moldability, the amount of the silicone resin powder blended is preferably 30 parts by mass or less based on 100 parts by mass of the total of the thermosetting resin (a), and the silicone resin powder is preferably used particularly in the range of 25 parts by mass or less. The lower limit of the amount of the silicone resin powder blended is not particularly limited but is preferably 1 part by mass or more, more preferably 3 parts by mass or more, in terms of sufficiently exhibiting the function as a flame-retardant aid.

Further, various polymer compounds such as other thermosetting resins, thermoplastic resins, and oligomers thereof, and elastomers, other flame-retardant compounds, additives, and the like can also be used in combination with the thermosetting resin (a) as required in a range in which the desired properties are not impaired. These are not particularly limited as long as they are generally used. Examples of the flame-retardant compounds include nitrogen-containing compounds such as melamine and benzoguanamine and oxazine ring-containing compounds. Examples of the additives include ultraviolet absorbing agents, antioxidants, photopolymerization initiators, fluorescent brightening agents, photosensitizers, dyes, pigments, thickening agents, lubricants, defoaming agents, dispersing agents, leveling agents, brightening agents, and polymerization inhibitors. One of these can be used alone or two or more of these can be used in combination according to the purpose.

Examples of the inorganic filler (b) include, but are not particularly limited to, silica, alumina, isinglass, mica, silicates, barium sulfate, magnesium hydroxide, and titanium oxide. Among these, silica and alumina are preferred, and particularly, silica such as amorphous silica, fused silica, crystalline silica, synthetic silica, and hollow silica is preferred. The silica is preferably spherical. One of these can be used alone or two or more of these can be used in combination according to the purpose. Especially, in terms of lowering the thermal expansion coefficient, fused silica is preferably used.

The average particle diameter (D50) of the inorganic filler (b) is not particularly limited but is preferably 5 μm or less, more preferably 4 μm or less, further preferably 3 μm or less, still further preferably 2 μm or less, especially preferably 1.5 μm or less, and particularly preferably 1 μm or less in terms of improving insulation reliability. On the other hand, the lower limit value of the average particle diameter (D50) of the inorganic filler (b) is preferably 0.01 μm or more, more preferably 0.05 μm or more, and further preferably 0.1 μm or more in terms of improving dispersibility. Especially, in terms of improving the impregnation properties of the resin varnish into the sheet-like fiber substrate to decrease the linear thermal expansion coefficient of the cured product, the inorganic filler (b) having an average particle diameter (D50) of 0.01 to 0.3 μm is preferably used as the inorganic filler (b).

Here, the average particle diameter (D50) of the inorganic filler can be measured by a laser diffraction-scattering method based on Mie scattering theory. Specifically, the average particle diameter (D50) of the inorganic filler can be measured by making the particle size distribution of the inorganic filler on a volume basis by a laser diffraction particle size distribution measuring apparatus and taking its median diameter as the average particle diameter. As the measurement sample, one obtained by ultrasonically dispersing the inorganic filler in water can be preferably used. As the laser diffraction particle size distribution measuring apparatus, LA-500 manufactured by HORIBA, Ltd., and the like can be used.

The content of the inorganic filler in the curable resin composition is not particularly limited but is preferably 1100 parts by mass or less, particularly preferably 1000 parts by mass or less, based on 100 parts by mass of the total of the thermosetting resin (a) in terms of preventing a decrease in the mechanical strength of the cured product or in terms of improving film thickness uniformity. On the other hand, the lower limit value of the content of the inorganic filler (b) in the curable resin composition is preferably 80 parts by mass or more, particularly preferably 90 parts by mass or more, based on 100 parts by mass of the total of the thermosetting resin (a) in terms of decreasing the thermal expansion coefficient or in terms of providing rigidity to the prepreg.

The above-described inorganic filler (b) is preferably treated with a surface treatment agent for the improvement of moisture resistance, dispersibility, or the like. Examples of the surface treatment agent used here include, but are not particularly limited to, aminosilane-based coupling agents such as aminopropylmethoxysilane, aminopropyltriethoxysilane, ureidopropyltriethoxysilane, N-phenylaminopropyltrimethoxysilane, and N-2 (aminoethyl)aminopropyltrimethoxysilane, epoxysilane-based coupling agents such as glycidoxypropyltrimethoxysilane, glycidoxypropyltriethoxysilane, glycidoxypropylmethyldiethoxysilane, glycidylbutyltrimethoxysilane, and (3,4-epoxycyclohexyl)ethyltrimethoxysilane, mercaptosilane-based coupling agents such as mercaptopropyltrimethoxysilane and mercaptopropyltriethoxysilane, silane-based coupling agents such as methyltrimethoxysilane, octadecyltrimethoxysilane, phenyltrimethoxysilane, methacryloxypropyltrimethoxysilane, imidazole silane, and triazine silane, organosilazane compounds such as hexamethyldisilazane, hexaphenyldisilazane, dimethylaminotrimethylsilane, trisilazane, cyclotrisilazane, and 1,1,3,3,5,5-hexamethylcyclotrisilazane, and titanate-based coupling agents such as a butyl titanate dimer, titanium octylene glycolate, diisopropoxytitanium bis(triethanolaminate), dihydroxytitanium bislactate, dihydroxybis(ammonium lactate)titanium, bis(dioctyl pyrophosphate)ethylene titanate, bis(dioctyl pyrophosphate)oxyacetate titanate, tri-n-butoxytitanium monostearate, tetra-n-butyl titanate, tetra(2-ethylhexyl)titanate, tetraisopropyl bis(dioctyl phosphite)titanate, tetraoctyl bis(ditridecyl phosphite)titanate, tetra(2,2-diallyloxymethyl-1-butyl)bis(ditridecyl)phosphite titanate, isopropyl trioctanoyl titanate, isopropyl tricumyl phenyl titanate, isopropyl triisostearoyl titanate, isopropyl isostearoyl diacryl titanate, isopropyl dimethacryl isostearoyl titanate, isopropyl tri(dioctyl phosphate)titanate, isopropyl tridodecyl benzenesulfonyl titanate, isopropyl tris(dioctyl pyrophosphate)titanate, and isopropyl tri(N-amidoethyl.aminoethyl)titanate. One of these can be used alone or two or more of these can be used in combination according to the purpose.

Regarding the inorganic filler (b), in order to improve the dispersibility of the inorganic filler or in order to improve the adhesive strength between the resin and the inorganic filler or the glass cloth, a silane coupling agent or a wetting and dispersing agent can also be contained in the thermosetting resin (a).

The silane coupling agent is not particularly limited as long as it is a silane coupling agent generally used for the surface treatment of inorganic matter. Specific examples thereof include, but are not particularly limited to, aminosilane-based silane coupling agents such as γ-aminopropyltriethoxysilane and N-β-(aminoethyl)-γ-aminopropyltrimethoxysilane, epoxysilane-based silane coupling agents such as γ-glycidoxypropyltrimethoxysilane, vinylsilane-based silane coupling agents such as γ-methacryloxypropyltrimethoxysilane, cationic silane-based silane coupling agents such as N-β-(N-vinylbenzylaminoethyl)-γ-aminopropyltrimethoxysilane hydrochloride, and phenylsilane-based silane coupling agents. One of these can be used alone or two or more of these can be used in combination according to the purpose.

The wetting and dispersing agent is not particularly limited as long as it is a dispersion stabilizer used for a paint. Examples thereof include, but are not particularly limited to, wetting and dispersing agents such as the registered trademark Disperbyk-110, 111, 180, 161, 2000, 2008, and 2009 and the registered trademark BYK-W996, W9010, and W903 manufactured by BYK Japan KK. One of these can be used alone or two or more of these can be used in combination according to the purpose.

The curable resin composition content in the prepreg is not particularly limited but is preferably 75% by mass or less, more preferably 70% by mass or less, further preferably 65% by mass or less, still further preferably 60% by mass or less, and especially preferably 55% by mass or less in terms of lowering the linear thermal expansion coefficient. In terms of improving close adhesiveness to the copper foils and suppressing the occurrence of voids, the curable resin composition content in the prepreg is preferably 30% by mass or more, more preferably 32% by mass or more, further preferably 34% by mass or more, still further preferably 36% by mass or more, especially preferably 38% by mass or more, particularly preferably 40% by mass or more, and especially preferably 42% by mass or more.

### [Sheet-Like Fiber Substrate]

The sheet-like fiber substrate used in the prepreg is not particularly limited, and one or two or more selected from glass fibers, organic fibers, glass nonwoven fabrics, and organic nonwoven fabrics can be used. Among them, in terms of decreasing the linear thermal expansion coefficient of the prepreg, sheet-like fiber substrates such as glass fibers, aramid nonwoven fabrics, and liquid crystal polymer nonwoven fabrics are preferred. Among these, glass fibers are more preferred, and glass cloths are further preferred. Among the glass fibers, in terms of being able to decrease the linear thermal expansion coefficient, E-glass fibers, T-glass fibers, and Q-glass fibers are preferred, and T-glass fibers and Q-glass fibers are more preferred, and Q-glass fibers are further preferred. The Q-glass fibers refer to glass fibers in which the content of silicon dioxide accounts for 90% or more.

The thickness of the sheet-like fiber substrate is not particularly limited. In terms of thinning the prepreg, the thickness of the sheet-like fiber substrate is preferably 200 μm or less, more preferably 175 μm or less, further preferably 150 μm or less, still further preferably 125 μm or less, especially preferably 100 μm or less, and particularly preferably 85 μm or less. In terms of improving the handling properties, the thickness of the sheet-like fiber substrate is preferably 1 μm or more, more preferably 5 μm or more, further preferably 10 μm or more, still further preferably 15 μm or more, especially preferably 20 μm or more, and particularly preferably 25 μm or more.

The method for manufacturing the prepreg is not particularly limited, but the following methods are preferred. The prepreg can be manufactured by a known hot melt method and solvent method and the like. The hot melt method is a method of once coating release paper having good releasability from a curable resin composition with the curable resin composition without dissolving it in an organic solvent, and laminating the coated release paper on a sheet-like fiber substrate, or directly coating a sheet-like fiber substrate with a curable resin composition by a die coater, or the like to manufacture a prepreg. The solvent method is a method of immersing a sheet-like fiber substrate in a resin composition varnish obtained by dissolving a curable resin composition in an organic solvent, to impregnate the sheet-like fiber substrate with the resin composition varnish, and then drying the resin composition varnish. The prepreg can also be prepared by continuously heat-laminating, on both surfaces of a sheet-like reinforcing substrate, adhesive films comprising a curable resin composition laminated on supports under heating and pressurization conditions.

The organic solvent used when the resin composition varnish is prepared include, but are not particularly limited to, ketones such as acetone, methyl ethyl ketone, and cyclohexanone, acetates such as ethyl acetate, butyl acetate, cellosolve acetate, propylene glycol monomethyl ether acetate, and carbitol acetate, carbitols such as cellosolve and butyl carbitol, aromatic hydrocarbons such as toluene and xylene, dimethylformamide, dimethylacetamide, and N-methylpyrrolidone. One of these can be used alone or two or more of these can be used in combination according to the purpose.

The drying conditions of the resin composition varnish are not particularly limited, but in terms of exhibiting higher adhesiveness in the vacuum heating and pressurization adhesion step, the curable resin composition needs to have moderate fluidity and adhesiveness. On the other hand, when a large amount of the organic solvent remains in the prepreg, the occurrence of blisters after curing may be caused. Therefore, the content of the organic solvent in the curable resin composition is preferably 5% by mass or less, more preferably 2% by mass or less. Specific drying conditions also differ depending on the curability of the curable resin composition, the amount of the organic solvent in the resin composition varnish, and the like. When a resin composition varnish comprising 30 to 60% by mass of an organic solvent is used, the resin composition varnish is preferably dried at 80 to 180° C. for 3 to 13 minutes. Preferred conditions can be appropriately set by performing a simple preexperiment considering the resin composition varnish and the like.

The thickness of the prepreg is not particularly limited but is preferably 20 μm or more, more preferably 25 μm or more, further preferably 30 μm or more, still further preferably 35 μm or more, and especially preferably 40 μm or more in terms of ensuring rigidity desired as the prepreg. In terms of thinning the metal foil-clad laminate, the thickness of the prepreg is preferably 250 μm or less, more preferably 180 μm or less, further preferably 150 μm or less, still further preferably 120 μm or less, and especially preferably 90 μm or less. The thickness of the prepreg can be easily controlled by adjusting the amount of the curable resin composition impregnated.

### [Metal Foils]

The metal foils are not particularly limited, but, for example, copper foils, aluminum foils, and the like are preferably used. Specific examples of commercial products include JTC foil (manufactured by JX Nippon Mining & Metals Corp.) and MT18Ex (manufactured by Mitsui Mining & Smelting Co., Ltd.).

### <Printed Wiring Board>

A printed wiring board can be manufactured by using the metal foil-clad laminate obtained by the manufacturing method of the present embodiment. The printed wiring board can be manufactured, for example, by the following method. First, the metal foil-clad laminate in the present embodiment is provided. The surfaces of this metal foil-clad laminate are subjected to etching treatment to form inner layer circuits to fabricate an inner layer board. The inner layer circuit surfaces of this inner layer board are subjected to surface treatment for increasing adhesive strength, as required. Then, the required number of the above-described prepregs are stacked on the inner layer circuit surfaces, metal foils for outer layer circuits are further laminated on the outside of the stack, and the laminate is heated and pressurized for integral molding. In this manner, a multilayer laminate in which an insulating layer comprising a sheet-like fiber substrate and a cured product of a thermosetting resin composition is formed between an inner layer circuit and a metal foil for an outer layer circuit is manufactured. Then, this multilayer laminate is subjected to perforation for through holes and via holes, and then, a plating metal film that allows conduction between the inner layer circuits and the metal foils for outer layer circuits is formed on the wall surface of this hole. Further, the metal foils for outer layer circuits are subjected to etching treatment to form outer layer circuits, and thus, a printed wiring board is manufactured. At this time, the resin composition layer of the metal foil-clad laminate obtained by the manufacturing method of the present embodiment (the layer comprising the curable resin composition in the present embodiment) constitutes an insulating layer in this printed wiring board.

### EXAMPLES

### Example 1

36 Parts by mass of an α-naphthol aralkyl-based cyanate compound (cyanate equivalent: 261 g/eq.) synthesized by a method described in Japanese Patent Laid-Open No. 2009-35728, 24 parts by mass of polyphenylmethane maleimide (BMI-2300, manufactured by Daiwa Kasei Co., Ltd.), and 40 parts by mass of a phenol biphenyl aralkyl-based epoxy resin (NC-3000-FH, epoxy equivalent: 320 g/eq., manufactured by Nippon Kayaku Co., Ltd.) were dissolved and mixed in methyl ethyl ketone. 2 Parts by mass of a wetting and dispersing agent (registered trademark Disperbyk-161, manufactured by BYK Japan KK), 190 parts by mass of spherical fused silica (SC2050 MB, manufactured by Admatechs Company Limited), 30 parts by mass of a silicone rubber powder whose surface was coated with a silicone resin (KMP-600, manufactured by Shin-Etsu Chemical Co., Ltd.), 0.02 parts by mass of zinc octylate (manufactured by Nihon Kagaku Sangyo Co., Ltd.), and 1 part by mass of 2,4,5-triphenylimidazole (manufactured by Wako Pure Chemical Industries, Ltd.) were further mixed with the obtained mixture to obtain a resin composition varnish. This varnish was diluted with methyl ethyl ketone, and a T-glass woven fabric having a thickness of 0.1 mm and a mass of 104 g/m² was impregnated and coated with the diluted varnish and heated and dried at 160° C. for 4 minutes to obtain a prepreg having a resin composition content of 50% by mass.

A 3 μm thick electrolytic copper foil (MT-Ex, manufactured by Mitsui Mining & Smelting Co., Ltd.) was disposed on each of the upper and lower surfaces of a stack obtained by stacking two of these prepregs, to provide a laminate. As the above-described adhesion step (A), this laminate was subjected to heating and pressurization treatment at a degree of vacuum of 0.05 kPa, a heating temperature of 130° C., and a pressure of 3 kgf/cm² for 60 seconds using a vacuum laminator CVP-600 manufactured by Nichigo-Morton Co., Ltd. to obtain an adhered body in which the copper foils were adhered to the prepregs. Next, as the above-described lamination molding step (B), lamination molding was performed at a degree of vacuum of 1 kPa, a heating temperature of 220° C., and a pressure of 10 kgf/cm² for 120 minutes using a multistage vacuum press for a printed wiring board to obtain a both-surface copper-clad laminate (both-surface metal foil-clad laminate) having a thickness of 0.2 mm.

### Example 2

A 3 μm thick electrolytic copper foil (MT-Ex, manufactured by Mitsui Mining & Smelting Co., Ltd.) was disposed on each of the upper and lower surfaces of a stack obtained by stacking two prepregs fabricated in Example 1, to provide a laminate. As the above-described adhesion step (A), this laminate was subjected to heating and pressurization treatment at a degree of vacuum of 0.05 kPa, a heating temperature of 130° C., and a pressure of 20 kgf/cm² for 60 seconds using a vacuum laminator CVP-600 manufactured by Nichigo-Morton Co., Ltd. to obtain an adhered body in which the copper foils were adhered to the prepregs. Next, as the above-described lamination molding step (B), lamination molding was performed at a degree of vacuum of 1 kPa, a heating temperature of 220° C., and a pressure of 10 kgf/cm² for 120 minutes using a multistage vacuum press for a printed wiring board to obtain a both-surface copper-clad laminate (both-surface metal foil-clad laminate) having a thickness of 0.2 mm.

### Example 3

Operation was performed as in Example 1 except that 940 parts by mass of alumina (AA-3, manufactured by Sumitomo Chemical Co., Ltd.) was used instead of the spherical fused silica, and the blending of the silicone rubber powder whose surface was coated with a silicone resin was omitted, to fabricate a prepreg. A 3 μm thick electrolytic copper foil (MT-Ex, manufactured by Mitsui Mining & Smelting Co., Ltd.) was disposed on each of the upper and lower surfaces of a stack obtained by stacking two prepregs made obtained in this manner, to provide a laminate. As the above-described adhesion step (A), this laminate was subjected to heating and pressurization treatment at a degree of vacuum of 0.05 kPa, a heating temperature of 140° C., and a pressure of 5 kgf/cm² for 60 seconds using a vacuum laminator CVP-600 manufactured by Nichigo-Morton Co., Ltd. to obtain an adhered body in which the copper foils were adhered to the prepregs. Next, as the above-described lamination molding step (B), lamination molding was performed at a degree of vacuum of 1 kPa, a heating temperature of 230° C., and a pressure of 10 kgf/cm² for 130 minutes using a multistage vacuum press for a printed wiring board to obtain a both-surface copper-clad laminate (both-surface metal foil-clad laminate) having a thickness of 0.2 mm.

### Example 4

A 3 μm thick electrolytic copper foil (MT-Ex, manufactured by Mitsui Mining & Smelting Co., Ltd.) was disposed on the top and the bottom on the upper and lower surfaces of a stack obtained by stacking two prepregs fabricated in Example 3. As the adhesion step (A), this laminate was subjected to heating and pressurization treatment at a degree of vacuum of 0.05 kPa, a heating temperature of 120° C., and a pressure of 15 kgf/cm² for 90 seconds using a vacuum laminator CVP-600 manufactured by Nichigo-Morton Co., Ltd. to obtain an adhered body in which the copper foils were adhered to the prepregs. Next, as the above-described lamination molding step (B), lamination molding was performed at a degree of vacuum of 2 kPa, a heating temperature of 220° C., and a pressure of 30 kgf/cm² for 130 minutes using a multistage vacuum press for a printed wiring board to obtain a both-surface copper-clad laminate (both-surface metal foil-clad laminate) having a thickness of 0.2 mm.

### Comparative Example 1

A both-surface copper-clad laminate (both-surface metal foil-clad laminate) having a thickness of 0.2 mm was obtained as in Example 1 except that instead of the lamination molding step (B), heat treatment was performed in a heating oven in the air at 220° C. for 120 minutes to thermally cure the curable resin composition.

### Comparative Example 2

A both-surface copper-clad laminate (both-surface metal foil-clad laminate) having a thickness of 0.2 mm was obtained as in Example 1 except that the adhesion step (A) was omitted, and the treatment conditions in the lamination molding step (B) were changed to a degree of vacuum of 2 kPa, a heating temperature of 220° C., and a pressure of 30 kgf/cm² for 130 minutes.

### Comparative Example 3

A both-surface copper-clad laminate (both-surface metal foil-clad laminate) having a thickness of 0.2 mm was obtained as in Example 3 except that the adhesion step (A) was omitted, and the treatment conditions in the lamination molding step (B) were changed to a degree of vacuum of 2 kPa, a heating temperature of 220° C., and a pressure of 30 kgf/cm² for 130 minutes.

### Comparative Example 4

A prepreg was fabricated as in Example 1 except that the amount of the spherical fused silica blended was changed to 60 parts by mass, and the amount of the blended silicone rubber powder whose surface was coated with a silicone resin was changed to 3 parts by mass. A both-surface copper-clad laminate (both-surface metal foil-clad laminate) having a thickness of 0.2 mm was obtained as in Example 1 except that the obtained prepreg was used, the adhesion step (A) was omitted, and the treatment conditions in the lamination molding step (B) were changed to a degree of vacuum of 2 kPa, a heating temperature of 220° C., and a pressure of 30 kgf/cm² for 130 minutes.

Using the adhered bodies obtained by the adhesion step (A), the peel strength of the copper foil was measured. Further, using the obtained both-surface copper-clad laminates, the moldability, thermal expansion coefficient, and glass transition temperature were evaluated. The results of these are shown in Table 1 and Table 2.

Peel strength of copper foil: A measurement sample was obtained by cutting the obtained both-surface copper foil-clad laminate to a size of 10×100 mm by a dicing saw and then leaving the copper foil on the surface. The peel strength of the copper foil of the measurement sample was measured according to Test methods of copper-clad laminates for printed wiring boards (see 5.7 Peel Strength), JIS C6481, using Autograph (manufactured by SHIMADZU CORPORATION: AG-IS) (average value for n=5).

Moldability: Blisters in the copper foils of the pressed both-surface copper-clad laminate were checked. In addition, the copper foils were etched, the appearance was observed, and the presence or absence of voids and the occurrence of unevenness from the ends were checked.

The thermal expansion coefficient and glass transition temperature were measured by the following methods after the metal-clad laminate was etched to remove the copper foils.

Thermal expansion coefficient: The temperature was increased by 10° C. per minute from 40° C. to 340° C. by a thermomechanical analyzer (manufactured by TA Instruments), and the linear expansion coefficient in the planar direction at 60° C. to 120° C. was measured. For the measurement direction, the longitudinal direction (Warp) of the glass cloth of the laminate was measured.

Glass transition temperature: The glass transition temperature was measured according to JIS C6481 by a dynamic viscoelasticity analyzer (manufactured by TA Instruments).

TABLE 1

| | Example 1 | Example 2 | Example 3 | Example 4 |
|---|---|---|---|---|
| Copper foil | Excellent | Excellent | Excellent | Excellent |
| blisters | | | | |
| Voids | Excellent | Excellent | Excellent | Excellent |
| Unevenness | Excellent | Good | Excellent | Good |
| Thermal | 3.1 | 3.1 | 5.4 | 5.4 |
| expansion | | | | |
| coefficient | | | | |
| Tg | 285 | 285 | 282 | 280 |
| Peel strength | 0.03 | 0.03 | 0.02 | 0.02 |
| after A step | | | | |
| [kN/m] | | | | |

Unit glass transition temperature: ° C.
thermal expansion coefficient: ppm/° C.

TABLE 2

| | Comparative | Comparative | Comparative | Comparative |
|---|---|---|---|---|
| | Example 1 | Example 2 | Example 3 | Example 4 |
| Copper foil | Poor | Excellent | Excellent | Excellent |
| blisters | | | | |
| Voids | Poor | Acceptable | Acceptable | Excellent |
| Unevenness | Excellent | Acceptable | Acceptable | Excellent |
| Thermal | — | 3.1 | 5.4 | 12.2 |
| expansion | | | | |
| coefficient | | | | |
| Tg | — | 283 | 281 | 281 |

Unit glass transition temperature: ° C.
thermal expansion coefficient: ppm/° C.

From Tables 1 and 2, it became clear that the metal foil-clad laminates obtained by Examples 1 to 4 had less voids and better moldability than Comparative Example 1 in which the lamination molding step (B) was not performed, and it became clear that the metal foil-clad laminates obtained by Examples 1 to 4 had less unevenness in the laminate and better appearance than Comparative Examples 2 and 3 in which the adhesion step (A) was not performed. In addition, from the comparison of Example 1 and Comparative Example 4, it became clear that when only the lamination molding step (B) was performed, the amount of the inorganic filler blended had to be decreased in order to suppress the occurrence of voids and unevenness, and in this case, it was shown that the thermal expansion coefficient was significantly reduced.

This application claims priority to Japanese Patent Application No. 2012-267446 filed with the Japan Patent Office on Dec. 6, 2012, and Japanese Patent Application No. 2012-287278 filed with the Japan Patent Office on Dec. 28, 2012, the content of which is incorporated herein by reference.

### INDUSTRIAL APPLICABILITY

As described above, the present invention can be widely and effectively utilized in various applications in which high insulation properties, a low thermal expansion coefficient, high heat resistance, or the like is required, such as electrical and electronic materials, machine tool materials, and aviation materials, and can be especially effectively utilized particularly in the field of printed wiring boards in which high heat resistance, a low thermal expansion coefficient, high peel strength of the metal foil, and the like are required.

1. A method for manufacturing a metal foil-clad laminate, comprising:
(A) an adhesion step of disposing one or more prepregs between metal foils so that the one or more prepregs are in contact with metal surfaces, and heating and pressurizing the one or more prepregs and the metal foils in a vacuum atmosphere to laminate the one or more prepregs and the metal foils to obtain a metal foil-clad laminate; and
(B) a lamination molding step of further subjecting the metal foil-clad laminate to heating and pressurization treatment in a vacuum atmosphere.

2. The method for manufacturing the metal foil-clad laminate according to claim 1, wherein in the adhesion step (A), the heating and pressurization treatment is carried out under conditions of a degree of vacuum of 0.001 to 1 kPa, a heating temperature of 50 to 180° C., and a pressurization pressure of 1 to 30 kgf/cm².

3. The method for manufacturing the metal foil-clad laminate according to claim 1, wherein in the lamination molding step (B), the heating and pressurization treatment is carried out under conditions of a degree of vacuum of 0.01 to 6 kPa, a heating temperature of 100 to 400° C., and a pressurization pressure of 1 to 40 kgf/cm².

4. The method for manufacturing the metal foil-clad laminate according to claim 1, wherein in the adhesion step (A), an adhered body having a peel strength of the metal foil of 0.01 to 0.1 kN/m is obtained.

5. The method for manufacturing the metal foil-clad laminate according to claim 1, wherein in the lamination molding step (B), the heating and pressurization treatment is performed using any of a multistage press, a multistage vacuum press, or a continuous molding machine.

6. The method for manufacturing the metal foil-clad laminate according to claim 1, wherein the prepreg is obtained by impregnating or coating a sheet-like fiber substrate with a curable resin composition comprising a thermosetting resin (a) and an inorganic filler (b).

7. The method for manufacturing the metal foil-clad laminate according to claim 6, wherein a content of the inorganic filler (b) in the prepreg is 80 to 1100 parts by mass based on 100 parts by mass of the thermosetting resin (a).

8. A printed wiring board using, for an insulating layer, a metal foil-clad laminate obtained by the manufacturing method according to claim 1.

9. The method for manufacturing the metal foil-clad laminate according to claim 2, wherein in the lamination molding step (B), the heating and pressurization treatment is carried out under conditions of a degree of vacuum of 0.01 to 6 kPa, a heating temperature of 100 to 400° C., and a pressurization pressure of 1 to 40 kgf/cm².

10. The method for manufacturing the metal foil-clad laminate according to claim 2, wherein in the adhesion step (A), an adhered body having a peel strength of the metal foil of 0.01 to 0.1 kN/m is obtained.

11. The method for manufacturing the metal foil-clad laminate according to claim 2, wherein in the lamination molding step (B), the heating and pressurization treatment is performed using any of a multistage press, a multistage vacuum press, or a continuous molding machine.

12. A printed wiring board using, for an insulating layer, a metal foil-clad laminate obtained by the manufacturing method according to claim 2.
